(19) United States
(12) Patent Application Publication
(10) Pub. No.: US 2015/0263210 A1
(43) Pub. Date: Sep. 17, 2015

(54) CIS/CGS/CIGS THIN-FILM MANUFACTURING METHOD AND SOLAR CELL MANUFACTURED BY USING THE SAME

(71) Applicant: KOREA INSTITUTE OF INDUSTRIAL TECHNOLOGY, Cheonan-si, Chungcheongnam-do (KR)

(72) Inventors: Tae Won Kim, Gwangsan-gu (KR); Jae Cheol Park, Jangseong-gun (KR); Ho Sung Kim, Gwangsan-gu (KR); Ik Hyun Oh, Buk-gu (KR); Jeon Ryang Lee, Seo-gu (KR); Bo Ra Koo, Dong-gu (KR); Seung Hyoun Lee, Nam-gu (KR)

(21) Appl. No.: 14/428,349

(22) PCT Filed: Dec. 26, 2012
(86) PCT No.: PCT/KR2012/011452

§ 371 Date: Mar. 13, 2015

(30) Foreign Application Priority Data
Sep. 17, 2012 (KR) 10-2012-0102728
Sep. 18, 2012 (KR) 10-2012-0103120
Sep. 26, 2012 (KR) 10-2012-0107171

(51) Int. Cl. H01L 31/0749; H01J 37/34; C23C 14/34

(52) U.S. Cl. CPC H01L 31/0749; C23C 14/34; H01J 37/3426

(57) ABSTRACT

Provided are a CIS/CGS/CIGS thin-film manufacturing method and a solar cell manufactured by using the same. The CIS/CGS/CIGS thin-film manufacturing method enables CIS, CGS, and CIGS thin-films through depositing an electrode layer on a substrate and depositing a light absorber layer by sputtering a single target of each of CIS including copper (Cu), indium (In), and selenium (Se) and CGS copper (Cu), gallium (Ga) and selenium (Se). In addition, a solar cell having excellent structural, optical and electrical properties is prepared by using the same. Thus, a thin-film can be prepared by depositing a CIG, CGS, or CIGS light absorber layer with a single sputtering process by using a single target of each of CIS (CuInSe2) and CGS (CuGaSe2), to thereby enable to manufacture thin-films of various characteristics according to a control of a composition ratio of In and Ga as well as simplification of the process, and to thus provide a very favorable effect on the economics and efficiency.

### CROSS-REFERENCE TO RELATED APPLICATIONS

This is a §371 US National Stage Application of International Application No. PCT/KR2012/011452 filed on Dec. 26, 2012, claiming the priority of Korean Patent Application No. 10-2012-0102728 filed on Sep. 17, 2012, Korean Patent Application No. 10-2012-0103120 filed on Sep. 18, 2012 and Korean Patent Application No. 10-2012-0107171 filed on Sep. 26, 2012.

### TECHNICAL FIELD

The present invention relates to a CIS/CGS/CIGS thin-film manufacturing method and a solar cell manufactured by using the same, and more particularly, to a CIS/CGS/CIGS thin-film manufacturing method in which a single target of each of CIS (CuInSe₂) and CGS (CuGaSe₂) having respectively different optical absorption coefficients are sputtered to thus perform a vapor deposition process of a light absorber layer, to thereby manufacture CGS, CIS and CIGS (CuInGaSe₂) thin-films with excellent optical properties and highly crystallographic stability in a single process, and a solar cell manufactured by using the same.

### BACKGROUND ART

As the recent increasing demand of energy, the development of a solar cell for converting solar energy into electrical energy has been proceeding.

In particular, CIGS-based thin-film solar cells are of low manufacturing cost and have band-gap energy (Eg) of 1.04 eV or so that is the most ideal for absorbing solar light, and thus have an advantage of a high conversion efficiency. As a result, a number of researches and developments of the CIGS-based thin-film solar cells have been made as thin-film solar cells.

A general CIGS-based thin-film solar cell has a basic structure as shown in FIG. 1, and is a device with a sequentially stacked structure of thin-film layers in an order of a substrate 11 made of glass, plastic, stainless steel, etc., a back contact layer 12, a p-type CIGS (CuInGaSe₂)-based light absorber layer 13, an n-type buffer layer 14, a window layer 15, an anti-reflection coating layer 16, and a counter electrode 17 corresponding to the back contact layer 12.

In the CIGS-based thin-film solar cell, the light absorber layer 13 absorbs light and generates electrical energy. A production method such as a co-evaporation process or a selenization process called a two-stage process of a metal precursor is the most widely used for manufacturing the CIGS-based thin-film solar cell.

In the case of the co-evaporation process, unit elements of copper (Cu), indium (In), gallium (Ga) and selenium (Se) are used as thermal evaporation sources and are simultaneously evaporated, to thereby form a light-absorber layer on a high temperature substrate formed of an electrode layer.

The selenization process of the metal precursor is also known as the two-stage process, and is made of the two-stage process including a precursor deposition process and a selenization process that performs a heat treatment process. In the selenization process, the metal precursors made of copper (Cu), indium (In), and gallium (Ga) are sequentially vacuum-deposited through a sputtering process on a substrate formed of an electrode layer, and then subjected to the selenization process at a high temperature, to thereby form a light absorber layer.

The co-evaporation process may increase the material consumption of copper, indium, gallium and selenium, may cause a low utilization efficiency of each unit element, and may be difficult to be applied for a large-area substrate.

The selenization process of the metal precursor should use hydrogen selenide (H₂Se) that is a toxic gas in the selenization process, and may have a non-uniform concentration of selenium (Se) and may have the difficulty in controlling a composition ratio of a CIGS thin-film.

In addition, the selenization process of the metal precursor may cause counter diffusion between copper (Cu), indium (In), gallium (Ga) and selenium (Se), and a unit element forming the electrode layer, at an interface between the electrode layer and the light absorber layer, while varying arrangement of conduction bands. In addition, since copper (Cu), indium (In), and gallium (Ga) are only used in a precursor forming process, a quality of a CGIS film may decline due to a volume expansion in the course of the subsequent selenization process.

As such, in the manufacture of the conventional CIGS-based thin-film solar cell, a light absorber layer is prepared by using a CIGS-based compound that is a quaternary compound. Accordingly, it is difficult to control the composition and process of the conventional CIGS-based thin-film solar cell.

### TECHNICAL PROBLEM

The present inventors have made efforts to form a light absorber layer by using a ternary compound comprising CIS (CuInSe₂) and CGS (CuGaSe₂) compositions, respectively, instead of CIGS (CuInGaSe₂) that is a quaternary compound, when performing deposition of the light absorber layer with a single process of using only a sputtering process without performing a post-process of a selenization process, and accordingly have developed a technical configuration of a CIS/CGS/CIGS thin-film manufacturing method and a solar cell is prepared by using the same, thereby completing the present invention.

Accordingly, to solve the above problems or defects, it is an object of the present invention to provide a CIS/CGS/CIGS thin-film manufacturing method in which a light absorber layer is formed with a single process of using only a sputtering process without performing a post-process of a selenization process by using a single target of each of CIS (CuInSe₂) and CGS (CuGaSe₂) having respectively different optical absorption coefficients, thereby providing a more simple, easier, and high efficient composition and process control, and a solar cell prepared by using the CIS/CGS/CIGS thin-film manufacturing method.

The objects to be solved in the present invention are not limited to the above-mentioned objects, and the other objects that are not mentioned in the present invention may be apparently understood by one of ordinary skill in the art in the technical field to which the present invention belongs.

### TECHNICAL SOLUTION

To accomplish the above and other objects of the present invention, according to an aspect of the present invention, there is provided a CIS/CGS/CIGS thin-film manufacturing method comprising the steps of: (a) preparing a substrate; (b) depositing an electrode layer on the substrate; and (c) depositing a light absorber layer by sputtering a single target of each of CIS (CuInSe₂) and CGS (CuGaSe₂).

According to another aspect of the present invention, there is provided a solar cell manufactured by using the CIS/CGS/CIGS thin-film manufacturing method.

### Advantageous Effects

As described above, the CIS/CGS/CIGS thin-film manufacturing method according to the present invention may form a light absorber layer with a sputtering process by using a single target of each of CIS (CuInSe₂) and CGS (CuGaSe₂), to thereby manufacture CGS, CIS and CIGS (CuInGaSe₂) thin films rapidly and efficiently via a simple process, to accordingly have a very beneficial effect in view of an economy and efficiency of a process when compared to the manufacture of the absorption layer prepared by using a typical selenization process.

In addition, the CIS/CGS/CIGS thin-film manufacturing method according to the present invention may easily control a composition ratio of a CIGS thin-film since an optical band gap of the CIGS thin-film that is deposited by a sputtering process of a single target of each of CIS (CuInSe₂) and CGS (CuGaSe₂) is varied at a constant rate according to a content ratio of indium (In) and gallium (Ga), to accordingly provide an effect capable of making the CIGS thin-film having excellent structural, compositional, and optical characteristics and properties.

Further, the present invention may manufacture solar cells by using the thus-prepared CGS, CIS and CIGS thin films, to thereby manufacture the solar cells with high efficiency and heighten cost-competitiveness such as mass production and cost reduction.

### DESCRIPTION OF DRAWINGS

FIG. 1 is a sectional view showing structure of a typical thin-film solar cell;

FIG. 2 is a flow chart showing a CIS/CGS/CIGS thin-film manufacturing method according to the present invention;

FIG. 3 is a conceptual schematic view of a sputtering apparatus for depositing a light absorber layer of a CIS/CGS/CIGS thin-film according to the present invention;

FIG. 4 is a view of a CIS thin-film sample prepared by a CIS thin-film manufacturing method according to the present invention;

FIGS. 5 and 6 are SEM views showing the surface and cross-sectional structures of a CIS thin-film prepared by the thin-film manufacturing method according to the present invention;

FIGS. 7 through 9 are graphs showing optical properties according to thickness of a CIS thin-film prepared by the thin-film manufacturing method according to the present invention;

FIG. 10 is a graph showing XRD results of a CIS thin-film prepared by thin-film manufacturing method according to the present invention;

FIG. 11 is a view showing a CGS thin-film sample prepared by the CGS thin-film manufacturing method according to the present invention;

FIG. 12 is a graph showing EDS analysis results of the CGS thin-film prepared by the CGS thin-film manufacturing method according to the present invention;

FIGS. 13 and 14 are SEM views showing the cross-sectional and surface structures of a CGS thin-film prepared by the thin-film manufacturing method according to the present invention;

FIGS. 15 through 17 are graphs showing optical properties according to thickness of a CGS thin-film prepared by the thin-film manufacturing method according to the present invention;

FIG. 18 is a graph showing XRD results of a CGS thin-film prepared by the thin-film manufacturing method according to the present invention;

FIG. 19 is a view of a CIGS thin-film sample prepared as a CIGS thin-film manufacturing method according to the present invention;

FIGS. 20 and 21 are SEM view showing cross-sectional and surface structures of CIGS thin-film made of a CIGS thin-film manufacturing method according to an embodiment of the present invention;

FIG. 22 is a graph illustrating transmission characteristics according to a composition ratio of In and Ga in a CIGS thin-film prepared by a CIGS thin-film manufacturing method in accordance with an embodiment of the present invention;

FIG. 23 is a graph showing band gap characteristics according to a composition ratio of In and Ga in a CIGS thin-film prepared by a CIGS thin-film manufacturing method in accordance with an embodiment of the present invention;

FIG. 24 is a graph showing Raman characteristics according to a composition ratio of In and Ga in a CIGS thin-film prepared by a CIGS thin-film manufacturing method in accordance with an embodiment of the present invention; and

FIG. 25 is a graph showing XRD characteristics according to a composition ratio of In and Ga in a CIGS thin-film prepared by a CIGS thin-film manufacturing method according to an embodiment of the present invention.

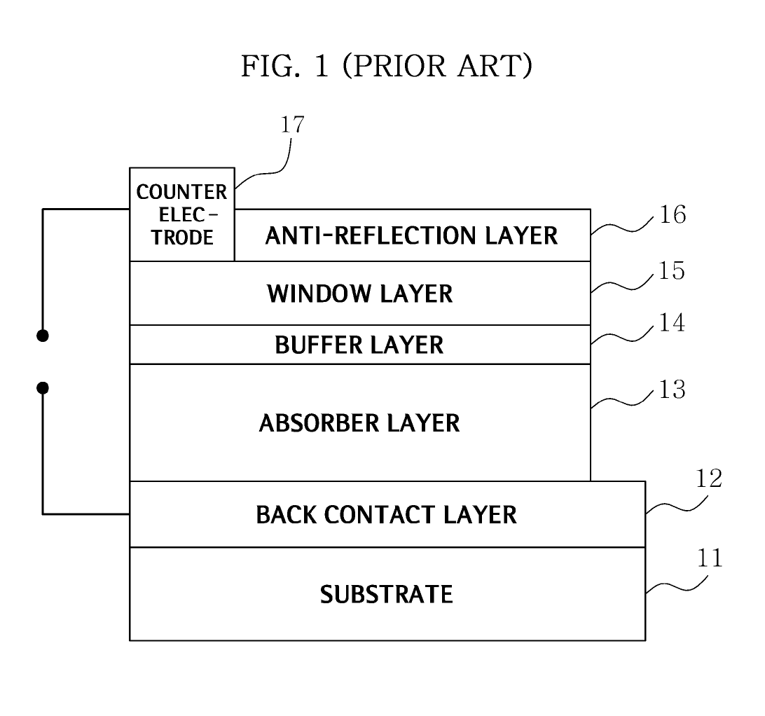

### BEST MODE FOR CARRYING OUT INVENTION

According to the best mode for carrying out the present invention, there is provided a CIS (CuInSe₂)/CGS (CuGaSe₂)/CIGS (CuInGaSe₂) thin-film manufacturing method comprising the steps of: (a) preparing a substrate; (b) depositing an electrode layer on the substrate; and (c) depositing a light absorber layer by sputtering a single target of each of CIS (CuInSe₂) and CGS (CuGaSe₂).

According to the best mode for carrying out the present invention, there is also provided a solar cell that is prepared by the CIS/CGS/CIGS thin-film manufacturing method.

Preferably but not necessarily, the depositing a light absorber layer of the step (c) comprises depositing a CIS light absorber layer by a RF sputtering or DC sputtering process by using a CIS single target including copper (Cu), indium (In), and selenium (Se).

Preferably but not necessarily, the depositing a light absorber layer of the step (c) comprises depositing a CGS light absorber layer by a RF sputtering or DC sputtering process by using a CGS single target including copper (Cu), gallium (Ga) and selenium (Se).

Preferably but not necessarily, the depositing a light absorber layer of the step (c) comprises depositing a CIGS light absorber layer by a simultaneous sputtering process by using a single target of each of CIS (CuInSe₂) and CGS (CuGaSe₂).

Preferably but not necessarily, the sputtering process is performed under the process conditions of power of 100 W (1.23 W/cm²) to 300 W (3.70 W/cm²), process pressure of 0.1 to 1.0 Pa, time of 0.5 to 2 hr, and ambient temperature of the normal temperature to 550° C.

Preferably but not necessarily, the single target of CIS (CuInSe₂) has a composition ratio of copper (Cu) of 0.8 to 1.0 and accordingly a composition ratio of selenium (Se) is Se₂+x in which x=0 to 0.2.

Preferably but not necessarily, the single target of CGS (CuGaSe₂) has a composition ratio of copper (Cu) of 0.8 to 1.0 and accordingly a composition ratio of selenium (Se) is Se₂+x in which x=0 to 0.2.

Preferably but not necessarily, the single target is located at a distance spaced by 100 mm to 150 mm from the substrate.

Preferably but not necessarily, the light absorber layer is characterized in that a thin-film thickness is regulated depending on the optical and structural properties, in which the CIS light absorber layer ranges from 0.1 μm to 2.0 μm, and a thin-film thickness of the CGS light absorber layer ranges from 0.3 μm to 2.2 μm.

Preferably but not necessarily, a thin-film thickness of the CIGS light absorber layer has an absorption wavelength of a constant rate according to a content ratio of gallium (Ga) and represents an absorption peak distribution within a wavelength range of 700 to 1200.

Preferably but not necessarily, a thin-film thickness of the CIGS light absorber layer has a constant optical band gap and a phase that varies consistently according to a content ratio of indium (In) and gallium (Ga).

### MODE FOR INVENTION

Embodiments of the present invention will be described below in detail with reference to the accompanying drawings. Here, the size or shape of the components illustrated in the drawings may be shown to be exaggerated for convenience and clarity of illustration. In addition, specifically defined terms may be changed according to the intention or practices of users or operators in consideration of the construction and operation of the present invention. The definition of the terms should be made based on contents throughout the present specification.

Hereinafter, a preferred embodiment of the present invention will be described below in detail with reference to the accompanying drawings.

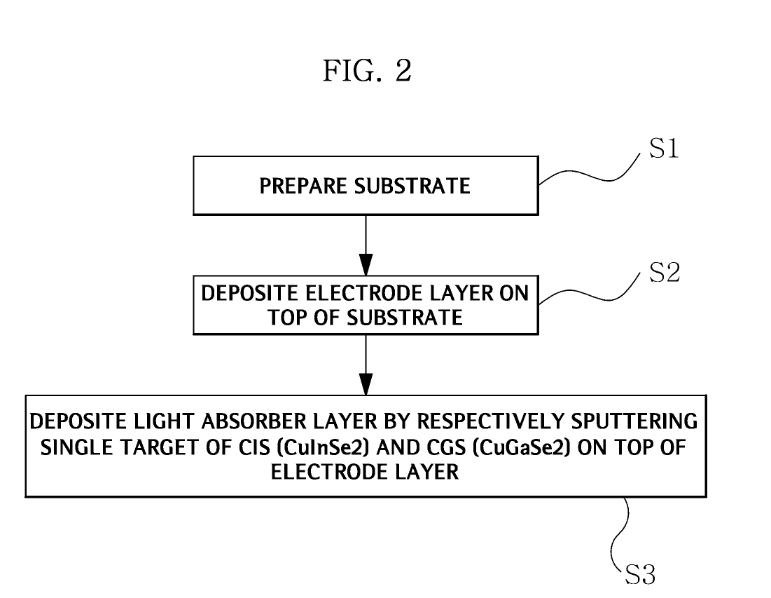

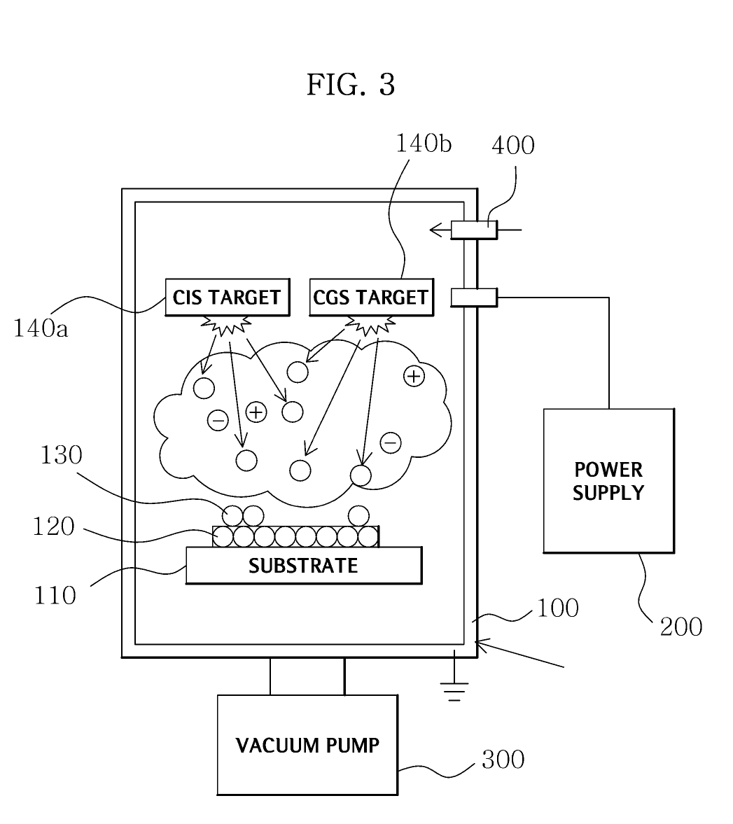

FIG. 2 is a flow chart showing a CIS/CGS/CIGS thin-film manufacturing method according to the present invention, and FIG. 3 is a conceptual schematic view of a sputtering apparatus for depositing a light absorber layer of a CIS/CGS/CIGS thin-film according to the present invention.

Referring to FIGS. 2 and 3, the CIS/CGS/CIGS thin-film manufacturing method according to the present invention prepares a substrate 110 (S1).

The substrate 110 may be formed of low-cost and high-efficiency soda lime glass (SLG) made of glass, in particular silica, lime and soda ash as main components. Besides, various materials such as stainless steel, a metal substrate, and polyimide (PI) can be used as the substrate 110.

After preparing the substrate 110, an electrode layer 120 is deposited on the upper portion of the substrate 110 (S2).

The electrode layer 120 may be formed of a material having a high electrical conductivity, and an excellent ohmic bonding with a light absorber layer 130. The electrode layer 120 may be formed of for example, molybdenum (Mo).

The thin-film made of molybdenum (Mo) should have a low resistivity as an electrode, and further have an excellent adhesion to the substrate 110, so that a peeling phenomenon does not occur due to difference in thermal expansion coefficients.

The electrode layer 120 can be formed by using a sputtering method, for example, a conventional direct-current (DC) sputtering method.

A light absorber layer 130 is deposited on the electrode layer 120. In addition, the light absorber layer 130 is made of one of a CIS (CuInSe₂)-based light absorber layer, a CGS (CuGaSe₂)-based light absorber layer, and a CIGS (CuInGaSe₂)-based light absorber layer, and can be deposited through a sputtering process.

In addition, a CIS single target 140a containing copper (Cu), indium (In) and selenium (Se) and a CGS single target 140b containing copper (Cu), gallium (Ga) and selenium (Se) are sputtered so that the light absorber layer 130 can be deposited in a short time efficiently. Here, the light absorber layer 130 can be deposited by using the sputtering process such as RF sputtering or DC sputtering (S3).

In addition, the CIS single target 140a is a CuInSe₂ compound of 99.9%. Preferably, when a composition ratio of copper is 0.8, 0.9, and 1.0, a composition ratio of selenium is provided with Se₂+x in which x=0.1, 0.2 and 0.3.

The CGS single target 140b is a CuGaSe₂ compound of 99.9%. Preferably, when a composition ratio of copper is 0.8, 0.9, and 1.0, a composition ratio of selenium is provided with Se₂+x in which x=0.2, 0.1 and 0.

In addition, in the process conditions according to the embodiment of the present invention, the process power was set as 100 W (1.23 W/cm²) to 300 W (3.70 W/cm²), the process pressure was set as 0.1˜1.0 Pa, the process time was set as 0.5˜2 hr, the distance (DTS) between the substrate 110 and the target 140a or 140b was set as 100˜150 mm, and the substrate temperature was set as the room temperature (R.T) to 550° C.

Under the process conditions, at the time of the RF sputtering process, the CIS single target 140a and the CGS single target 140b are attached to a cathode of the inside of the vacuum chamber 100, and the substrate 110 on which the electrode layer 120 is deposited is spaced at a predetermined distance, that is, 100˜150 mm or so, from the CIS and CGS single targets 140a and 140b, to then be attached to an anode of the inside of the vacuum chamber 100.

Next, at the time of the RF sputtering process, an inert gas such as helium (He) or argon (Ar) is injected into the inside of the vacuum chamber 100 through a gas injection unit 400, and then the internal pressure of the vacuum chamber 100 is maintained at 0.1 to 1.0 Pa. In other words, after the injection of the inert gas into the vacuum chamber 100 that is in a high vacuum state of 6 to 10 Pa, the process pressure is maintained in the range of 0.1 to 1.0 Pa.

Next, at the time of the RF sputtering process, the power of 100 W (1.23 W/cm²) to 300 W (3.70 W/cm²) is applied to the vacuum chamber 100 through the power supply 200, thereby generating plasma inside the vacuum chamber 100, while the elements of the CIS single target 140a and the CGS single target 140b are released to then be deposited on top of the electrode layer 120 to thus constitute a light-absorber layer 130.

The light absorber layer 130 constitutes a CIS light absorber layer thin-film when the elements of the CIS single target 140a are released, constitutes a CGS light absorber layer thin-film when the elements of the CGS single target 140b are released, and constitutes a CIGS light absorber layer thin-film when the elements of the CIS single target 140a and the CGS single target 140b are simultaneously released.

That is, since copper (Cu), indium (In) and selenium (Se) are contained in the CIS single target 140a, and copper (Cu), gallium (Ga) and selenium (Se) are contained in the CGS single target 140b, and the light absorber layer 130 can be deposited with a single process through the RF sputtering process, the light absorber layer 130 can be deposited simply and quickly, without the need for a separate post-process after selenization.

Meanwhile, the light absorber layer 130 may be deposited with the DC sputtering process. At the time of the DC sputtering process, the light absorber layer 130 can be deposited with a single process by using the single targets 140a and 140b, as in the case of the RF sputtering process. However, the DC sputtering process differs from the RF sputtering process in a point that the power that is applied to the single targets 140a and 140b is direct-current power, but the former is the same as the latter in a point that the light absorber layer 130 can be deposited simply and quickly, without the need for a separate post-process after selenization.

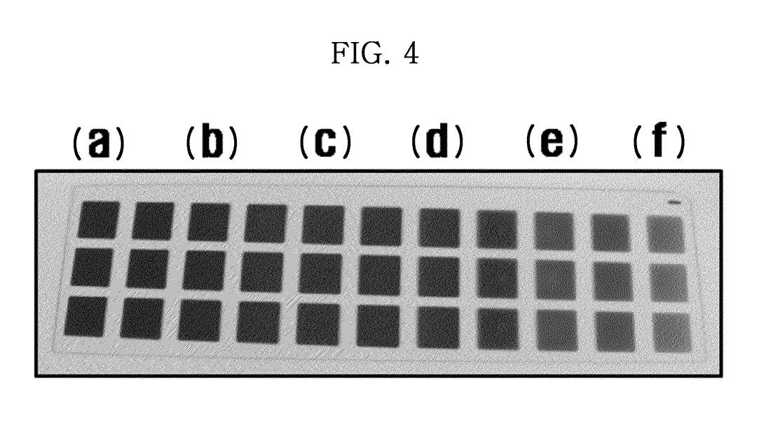

Samples of the CIS thin-film according to the present invention are shown in FIG. 4, in which the samples of the CIS thin-film are manufactured with a single process of the sputtering process using the single target 140a made of CuInSe₂.

As shown in FIG. 4, it can be seen that the CIS thin-film prepared by using a CIS thin-film manufacturing method according to the present invention have a constant thickness depending upon the slope of the thin-film. Here, as it goes towards the sample “a,” distance between the substrate and the target becomes close to thus thicken the thickness of the thin-film. Each of the thin-films can be compared and analyzed, to thereby confirm the optimal absorber layer condition.

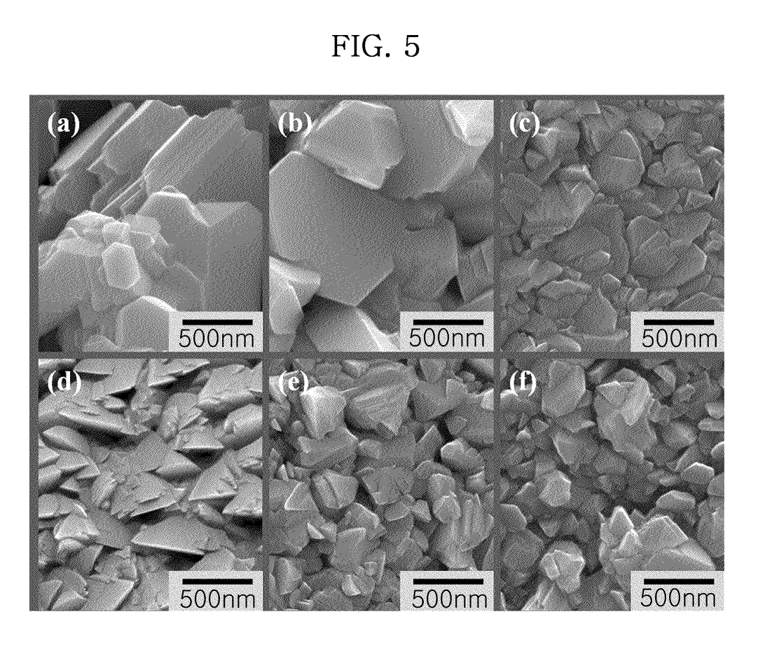

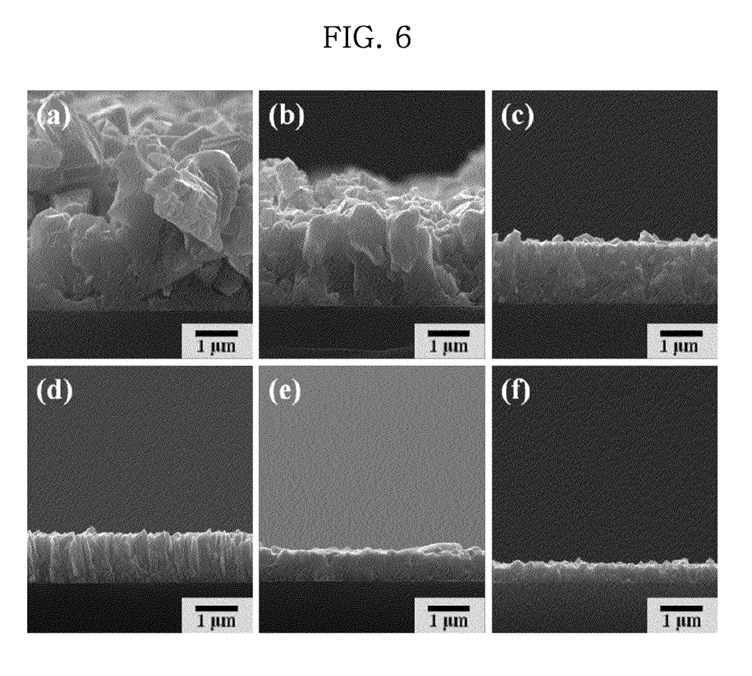

FIGS. 5 and 6 are SEM views respectively showing a surface structure and a cross-sectional structure according to the thickness of the CIS thin-film that was prepared by using a CIS thin-film manufacturing method according to the present invention. Here, the thickness of the thin-film was set as “a” (4.2 μm), “b” (2.5 μm), “c” (1.5 μm), “d” (1.2 μm), “e” (0.7 μm), and “f” (0.5 μm).

Referring to FIG. 5, grain boundaries having a clear crystal structure can be observed from the surface of the CIS thin-film prepared by the CIS thin-film manufacturing method according to this invention, and it can be seen that grain size is increased as the thickness of the thin-film becomes larger.

Referring to FIG. 6, it can be seen that the CIS thin-film prepared by the CIS thin-film manufacturing method according to the invention has an excellent adhesion characteristic with respect to the substrate 110 in the cross section thereof. That is, in the case of “c” to “f” where the thickness of the CIS thin-film is not more than 2 μm, the CIS thin-film has an excellent adhesion characteristic. However, in the case of “a” and “b” where the thickness of the CIS thin-film is larger than 2 μm, it can be seen that grain size becomes large but shows a rough surface characteristic and the coarse thin-film property.

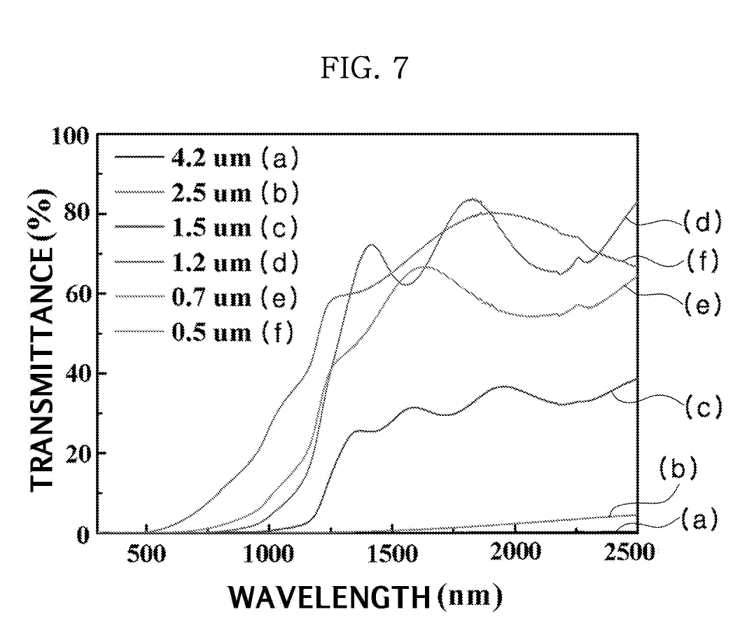

FIGS. 7 through 9 are graphs showing optical properties according to thickness of a CIS thin-film prepared by the CIS thin-film manufacturing method according to the present invention, and show the transmission characteristic, the band gap, and the crystallinity.

In the graph showing optical properties according to the thickness of the CIS thin-film of FIG. 7, the transverse axis represents the wavelength, and the vertical axis represents the transmittance.

Referring to FIG. 7, it can be seen that the CIS thin-film prepared by the CIS thin-film manufacturing method according to the invention shows the first absorption peak appearing in the wavelength region of about 1200˜1300 nm, except for the thickness of 2.5 μm or more. It can be seen that the CIS thin-film has properties similar to those of thin-films subjected to the selenization process with a value of about 0.97˜1.04 eV when the first absorption peak is converted into the optical band gap energy, and has a very excellent characteristic when compared with a process having carried out by using only a single target 140a.

For a thin-film having a thickness of 2.5 μm or more, it can be seen that it is difficult to observe the change of the transmission characteristics, and it is requisite to control of the thin-film thickness, considering the economical efficiency of the process of the thin-film and the efficiency of the light absorber layer 130 simultaneously.

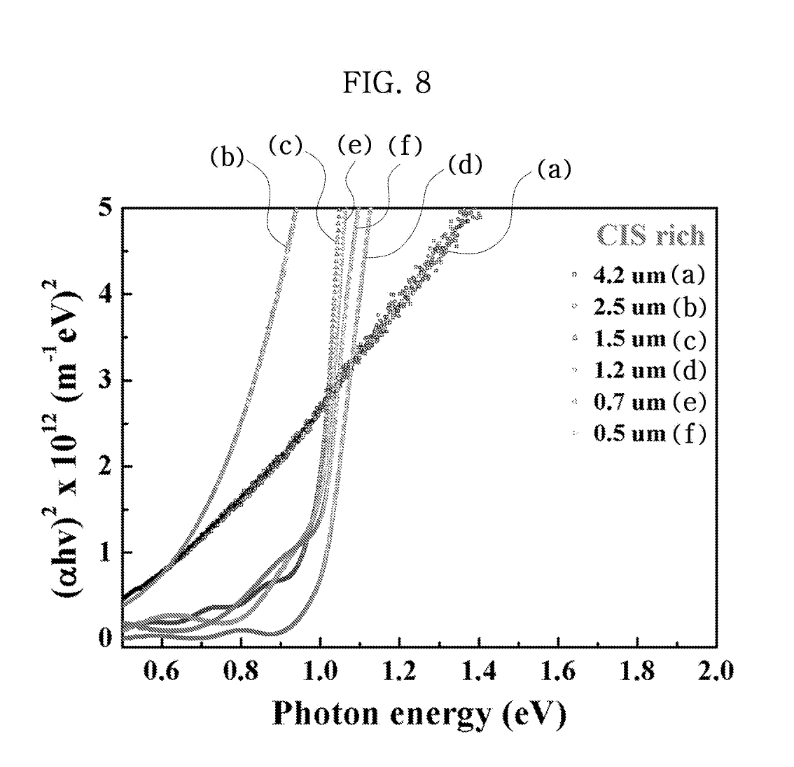

When a value of (αhv)² corresponding to hv (h=Planck constant, v=frequency) is plotted by using the transmission characteristics shown in the FIG. 7 graph, it can be expressed as the optical band gap characteristic graph as shown in FIG. 8.

Referring to FIG. 8, the optical band gap having a value of 0.96˜1.05 eV can be confirmed in the CIS thin-film having a thickness of 2.5 μm or less. As shown in FIG. 6, the CIS thin-film of 2.5 μm and 4.2 μm thick has too a low permeability with respect to the substrate, and thus the inflection point where absorption or permeation is performed does not appear. Accordingly, it can be seen that the band gap cannot be confirmed, but CIS thin-films having a thickness of not more than 2 μm shows stable characteristics the optical band gap does not change significantly without the selenization process.

The optical band gap (a=[ln(1/T)]/t; T=transmittance, and t=thin-film thickness) of the CIS thin-film may vary depending on the thickness factor of the thin-film and the composition ratio of copper (Cu), indium (In) and selenium (Se).

Therefore, it is possible to manufacture the CIS thin-film having stable optical properties satisfying control of the optimum thin-film thickness of the light absorber layer and the stable composition ratio characteristic in terms of stoichiometry, by using only a single sputtering target.

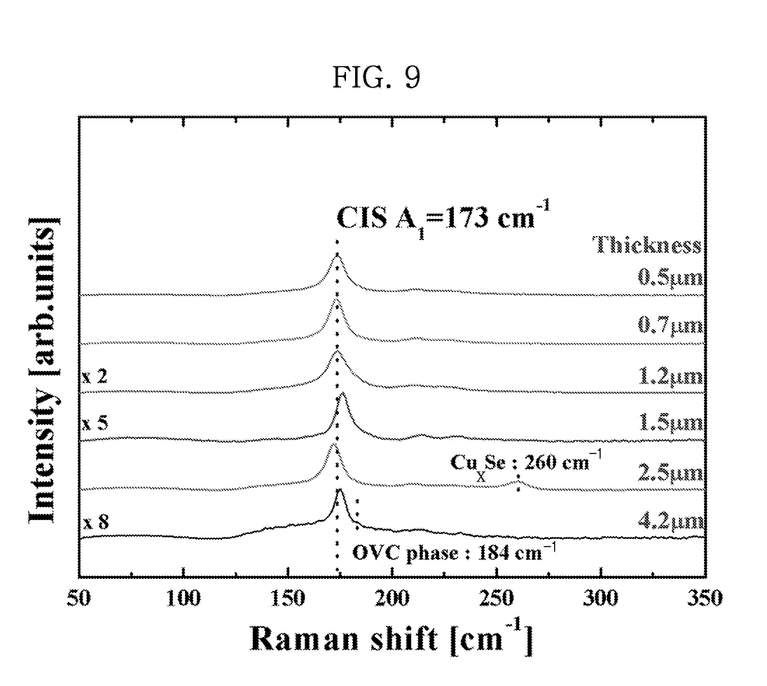

FIG. 9 is a graph of the Raman spectrum analysis of the CIS thin-film. Here, monocrystallinity, polycrystallinity or secondary phases of the CIS thin-films made of a different thickness were determined through Raman PL. In the case of the CIS thin-film generally having a monocrystalline property, Raman peaks were observed at 173 cm⁻¹, and has a full width at half maximum (FWHM) value of about 9˜10 cm⁻¹. In the case of the CIS thin-film of the thin-film thickness of 0.5 μm−4.2 μm, the Raman shift was demonstrated at the value of 173˜174 cm⁻¹, and exhibited a full width at half maximum value of 8˜11 cm⁻¹. It can be seen that the thin-film of the light absorber layer produced by using only the single CIS sputtering target shows an excellent monocrystalline property, and excellent properties that are not crystallographically lowered when compared to the thin-film of the light absorber layer produced by using the selenization method of the conventional metal precursors.

In the case of the CIS thin-film having the film thickness of 2 μm or more, it can be seen that the monocrystalline properties were exhibited and simultaneously characteristic peaks (OVC phase: 184 cm⁻¹, CuxSe: 260 cm⁻¹) having a stoichiometric unstable composition were observed.

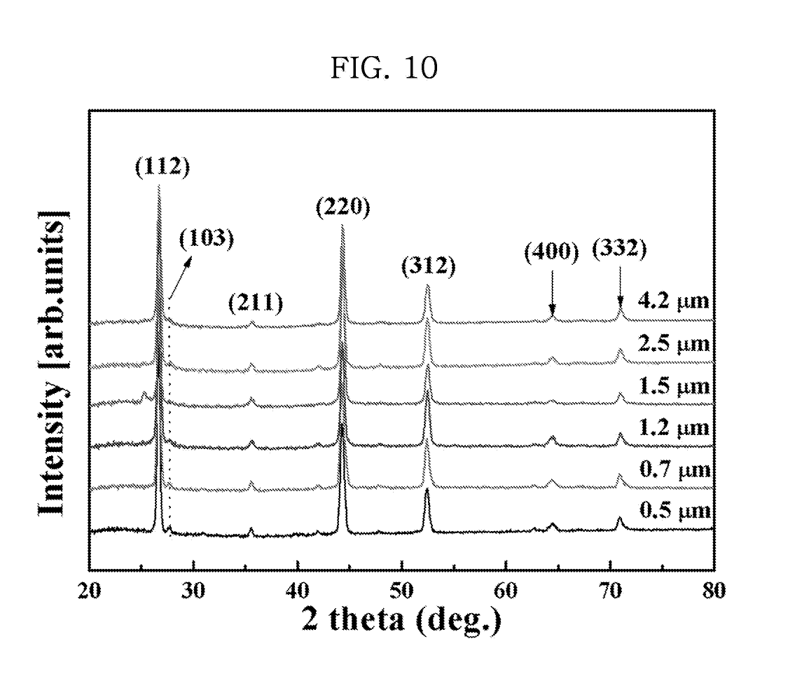

FIG. 10 is a graph showing XRD results of CIS thin-films according to the present invention.

Referring to FIG. 10, the CIS thin-films according to the present invention were ascertained that characteristic peaks (103) and (211) showing the chalcopyrite structure were found at all the film thicknesses of 0.5 μm−4.2 μm. It can be seen that the peaks associated with binary phases such as copper (Cu)-selenium (Se) or indium (In)-selenium (Se) were not detected, which is consistent with a point that the other phases except the CIS thin-film were not found, when compared to and analyzed with the Raman data.

In addition, all the diffraction peaks {(112), (220), (312), (400), and (332)} identified in the 2 theta (A) range of 20˜80 degrees were the characteristic peaks having only the chalcopyrite structure, but peak positions having the binary phase or sphalerite structure were not found.

Accordingly, according to the present invention, it can be seen that the CIS thin-film is prepared with an initial one step by using only a single sputtering target, to thereby be very advantageous in terms of the economy and efficiency than a conventional sputtering method which requires a selenization process, and to thus have excellent structural and optical properties by adjusting the thickness of the CIS thin-film.

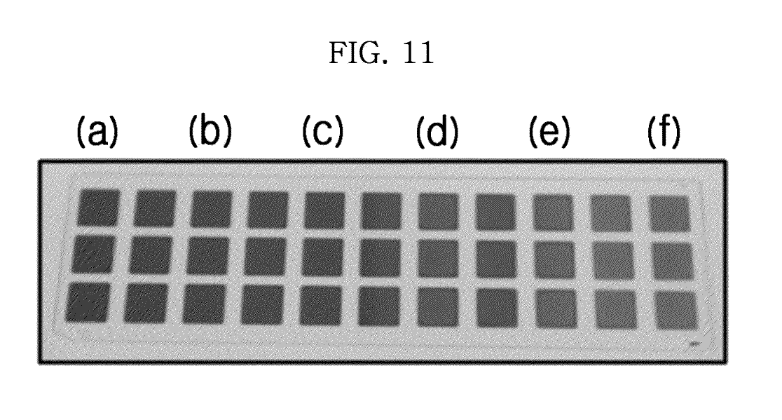

Next, samples of the CGS thin-film that is manufactured in a single sputtering process using a single target 140b with a composition of CuGaSe₂ according to the present invention are shown in FIG. 11.

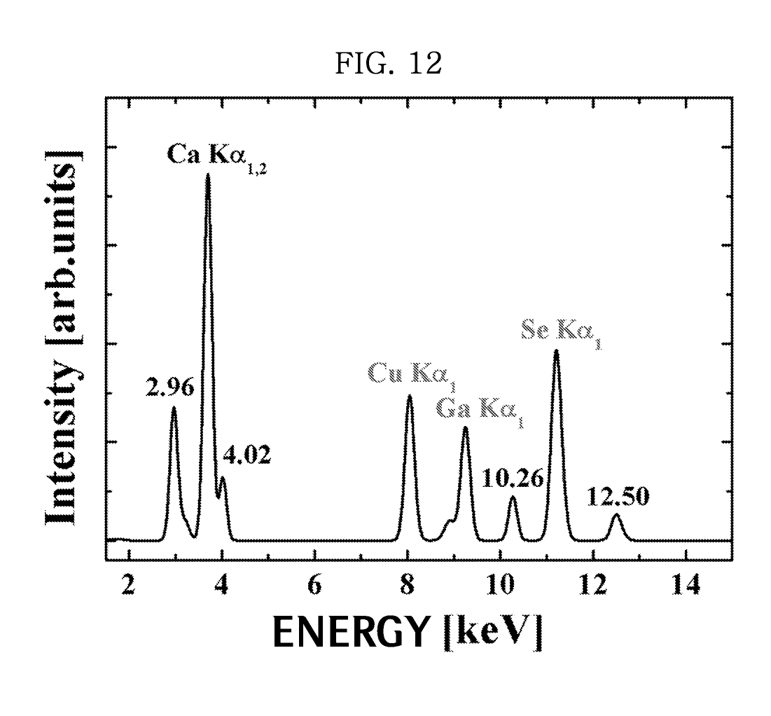

As shown in FIG. 11, the CGS thin-films prepared by the thin-film manufacturing method according to the present invention were manufactured to have a different thin-film thickness gradient. That is, the CGS thin-films were prepared to have a different thickness, respectively, in which as it goes toward the sample (f), the distance to the target from the sample gets far, and as it goes toward the sample (a), the distance to the target from the sample gets close. The results of comparing and analyzing the structural, optical, and electrical characteristics of each of the thin-films are shown in FIGS. 12 to 18.

FIG. 12 is a graph showing EDS analysis results of analyzing a composition of copper (Cu), gallium (Ga) and selenium (Se) according to the thin-film thickness of the CGS light absorber layer 130 deposited according to an embodiment of the present invention, through EDS (Energy Dispersive Spectroscopy).

Referring to the graph of FIG. 12, it was confirmed that atoms of copper (Cu), gallium (Ga) and selenium (Se) each had an energy value of 8.047, 9.254 and 11.222 keV when they were transitioned to the Kα1 shell. This means that the composition of the single target 140b was effectively deposited with a single step through a sputtering process.

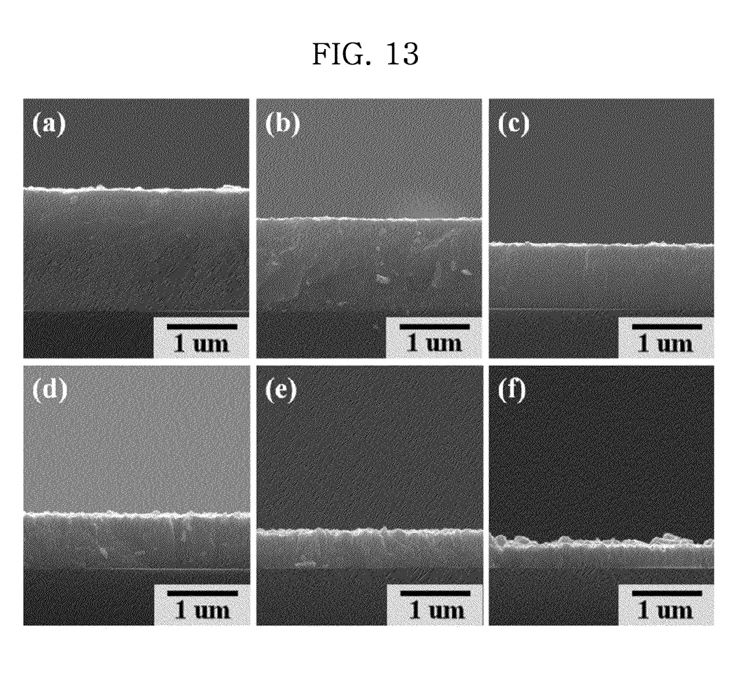

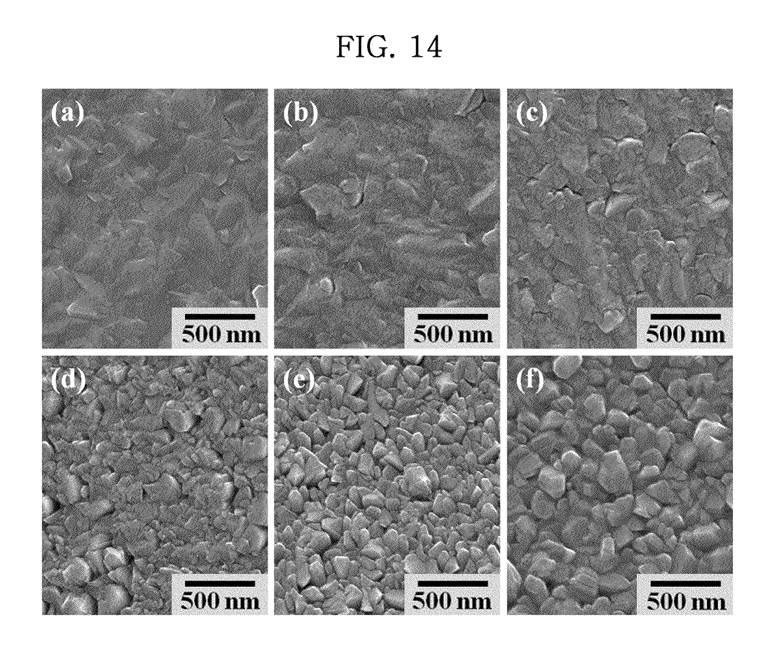

FIGS. 13 and 14 are SEM views showing the cross-sectional and surface structures depending upon the thicknesses of CGS thin-films prepared by the CGS thin-film manufacturing method according to the present invention. Here, the thicknesses of the thin-films were set to “a” (2.2 μm), “b” (1.7 μm), “c” (1.2 μm), “d” (0.8 μm), “e” (0.6 μm), and “f” (0.3 μm).

As shown in “a” to “f” of FIG. 13, it can be seen that the CGS thin-films prepared by the CGS thin-film manufacturing method according to the invention showed the thin-film characteristics of a very high contact force and packing density, with respect to the substrate depending on the thicknesses of the thin-films.

In addition, it can be seen that the CGS thin-films prepared by the CGS thin-film manufacturing method according to the invention showed the surface properties as shown in “a” to “f” of FIG. 14. The surface roughness of the thin-film is changed depending on the process power, process pressure, process time, the distance between the target and the substrate, the process gas, and the substrate temperature, and the CGS thin-films prepared under the optimum process conditions according to the present invention have properties as shown in “a” to “f” of FIG. 14.

When preparing a CGS thin-film on a substrate, by using a CGS sputtering target having a composition ratio of CuGaSe₂ in terms of the stoichiometry, the grain size of the CGS thin-film and the packing density of the thin-film surface exhibited a tendency to increase as the thickness of the sample becomes large.

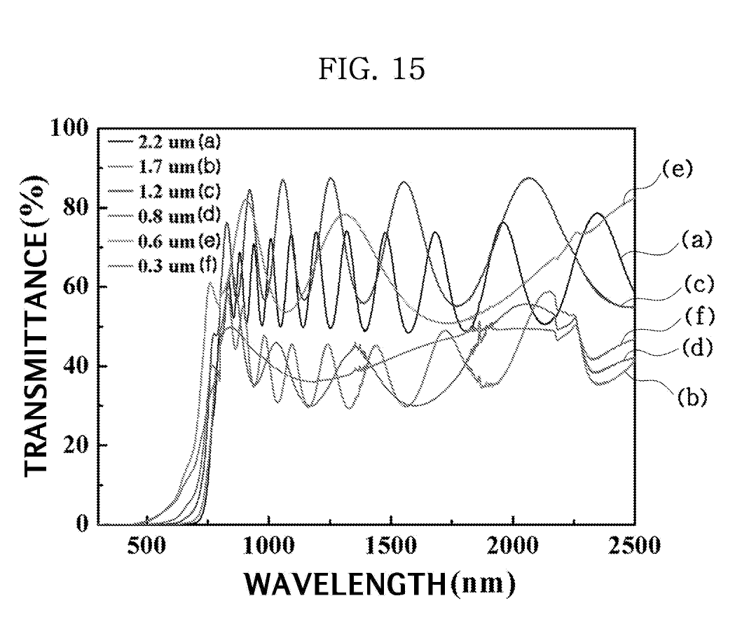

FIG. 15 is a graph illustrating transmission characteristics according to the thicknesses of the CGS thin-films prepared by the CGS thin-film manufacturing method according to the present invention, in which the horizontal axis represents the wavelength, and the vertical represents the transmittance.

Referring to the transmission characteristics of the CGS thin-film shown in FIG. 15, it can be seen that the CGS thin-films “a” to “f” having a thickness gradient of about 0.3 μm to 2.2 μm had the first absorption peak in the wavelength band of about 700˜800 nm for the entire samples. It can be seen that the CGS thin-film had a value of about 1.55˜1.77 eV when the first absorption peak is converted into the optical band gap energy, and showed a very close value when compared with the case where the optical band gap energy of the CGS thin-film that is typically grown as monocrystals is about 1.6 eV.

It can be seen that the optical properties of the CGS thin-film produced with the single target 140b and without a complicated process have only shown a very stable characteristic, and thus it is possible to produce an excellent CGS thin-film without using a high cost, high-risk material due to the selenization process.

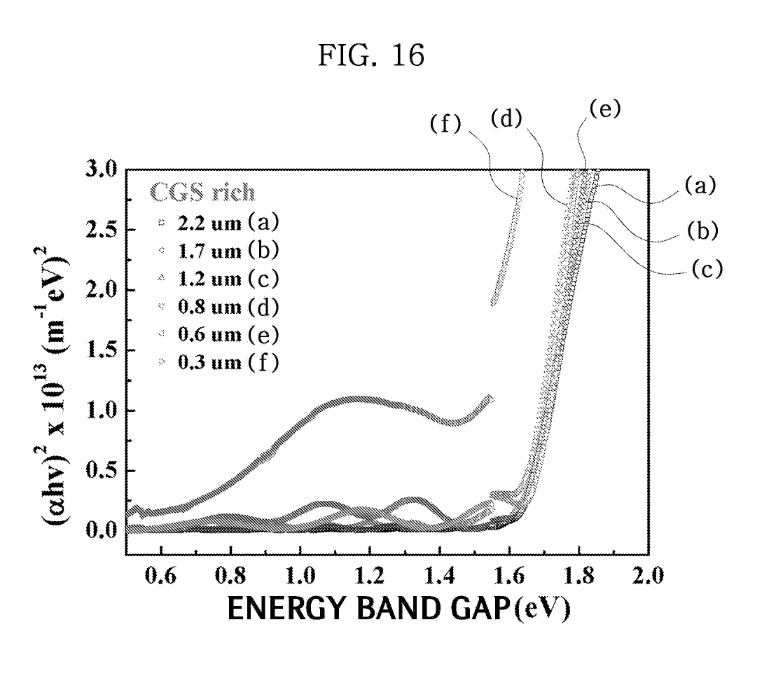

FIG. 16 is a graph showing the optical band gap characteristics of the CGS thin-films prepared by the CGS thin-film manufacturing method according to the invention.

The graph shown in FIG. 16 was obtained by plotting a value of (αhv)² corresponding to hv by using the transmission characteristics of the CGS thin-film shown in the FIG. 15 graph, and exhibited the optical band gap having a value of 1.6 eV for all samples except for the sample having a thin-film thickness of 0.3 μm. The optical properties of the CGS thin-films deposited with only a single sputtering target by RF sputtering method can be seen to represent an excellent characteristic as compared with the thin-film subjected to an existing commercially available selenization process.

In addition, the sputtering method using the CGS single target has the advantages of reduction of the process time, simplification of the process steps, and non-use of toxic materials.

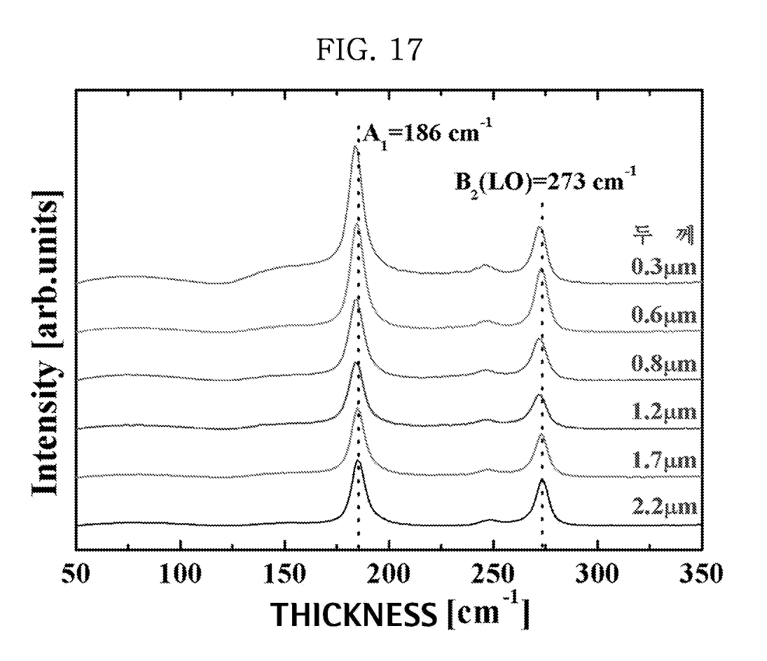

FIG. 17 is a graph showing the Raman characteristics of the CGS thin-films prepared by the CGS thin-film manufacturing method according to the present invention.

Referring to the graph shown in FIG. 17, the monocrystallinity, polycrystallinity or secondary phases of the CGS thin-films made of a different thickness gradient were confirmed through Raman PL. In the case of the CGS thin-film generally having a monocrystalline property, Raman peaks were observed at A1 mode (186 cm⁻¹), and B2 mode (273 cm⁻¹). In the case of the CGS thin-films of the thin-film thicknesses of 0.3 μm−2.2 μm by using a CGS single target, the precise Raman shift values were demonstrated at the A1 and B2 modes for all samples, which exhibited excellent monocrystalline characteristics of the light-absorbing thin-films that were manufactured by using only a single CGS sputtering target.

In addition, the CGS thin-films grown on the substrate 110 were confirmed as only CGS phases that match stoichiometrically, and the binary phases Cu—Se, In—Ga, and Ga—Se or the compositionally unstable phase Cu—Ga—Se did not appear.

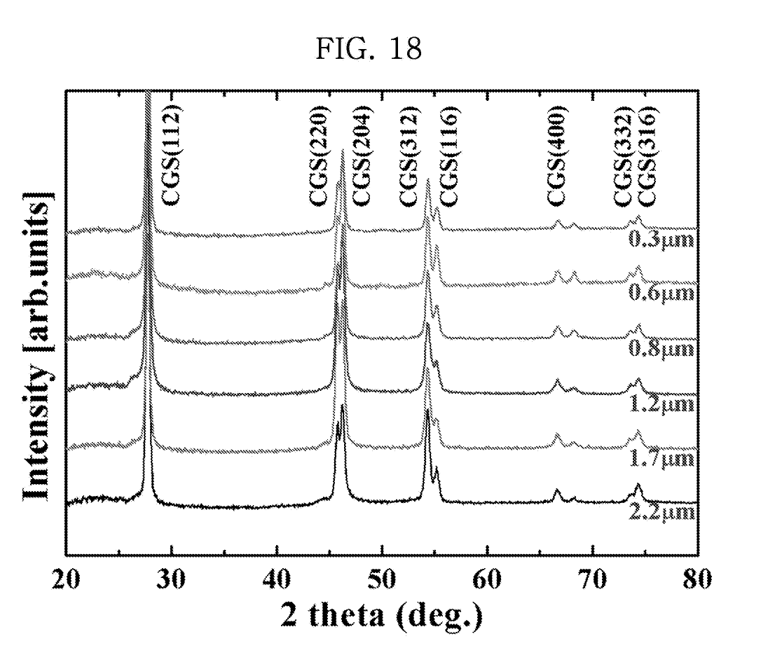

FIG. 18 is a graph showing XRD results of CGS thin-films according to the present invention.

Referring to FIG. 18, the CGS thin-films according to the present invention were ascertained that only diffraction peaks {(112), (220), (204), (312), (116), (400), (332), and (316)} indicative of a chalcopyrite characteristic were found, and the peaks associated with binary phases such as copper (Cu)-selenium (Se), indium (In)-selenium (Se), or gallium (Ga)-selenium (Se) were not detected, which showed excellent crystalline characteristics of the CGS thin-films prepared by using only a single target, and suggested that it is possible to manufacture a high-quality solar cell absorber layer with only one process in addition to stable optical characteristics.

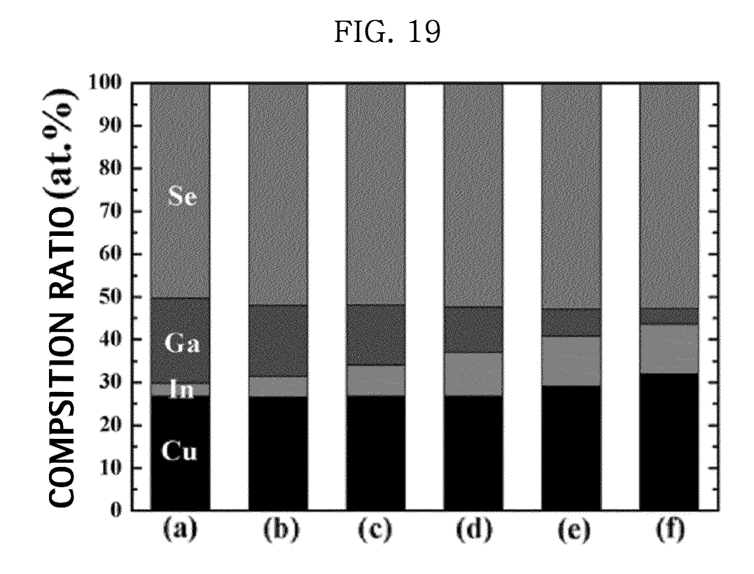

Next, samples of the CIGS thin-film that is manufactured through the above process according to the present invention are shown in FIG. 19.

As shown in FIG. 19, the CIGS thin-films by a CIGS thin-film manufacturing method according to the present invention were made to have various types of the composition ratios of (In, Ga), in which as it goes toward the sample “a,” the CIGS thin-film increasingly dominated a CGS-rich region and as it goes toward the sample “f,” the CIGS thin-film increasingly dominated a CIS-rich region. Here, as shown in FIG. 19, in accordance with samples “a” to “f,” the CIGS thin-films were prepared so hat a composition ratio of (In, Ga) was variously distributed.

Referring to FIG. 19, the horizontal axis represents the samples “a” to “f,” and the vertical axis represents the composition ratio (at.%). It can be seen that as it goes toward the sample “a,” the content of indium (In) decreases and the content of gallium (Ga) increases. Reversely, as it goes toward the sample “f,” the content of indium (In) increases and the content of gallium (Ga) decreases. In other words, it can be seen that a composition ratio of (In, Ga) was variously distributed in accordance with each of samples “a” to “f.”

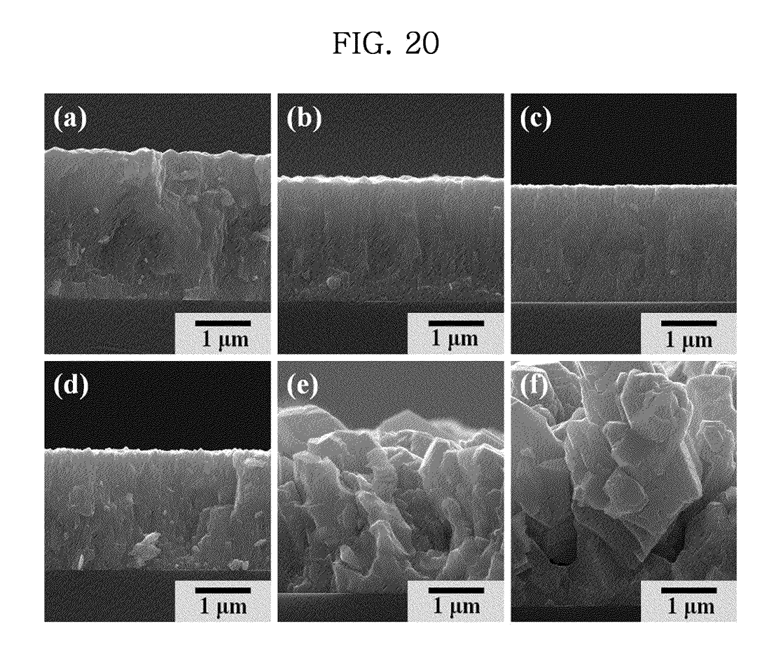

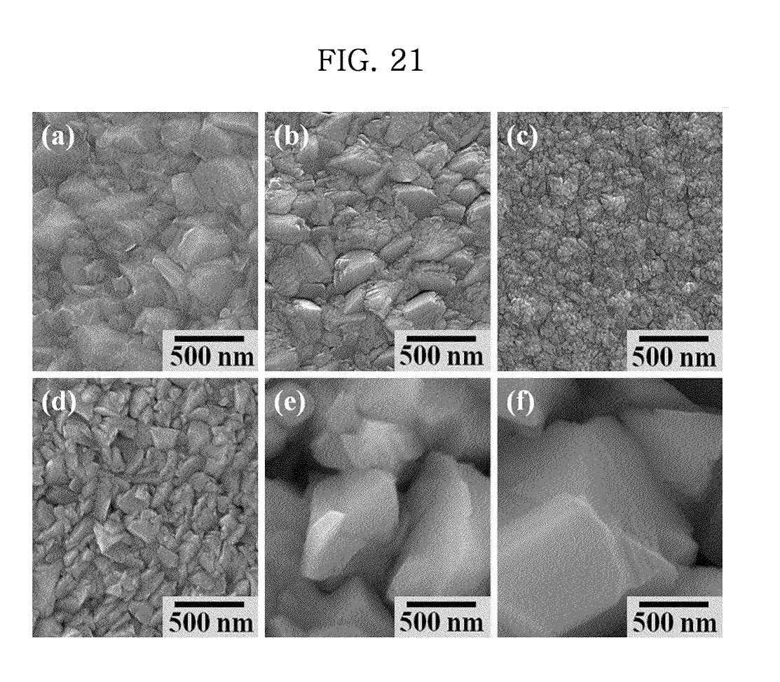

FIGS. 20 and 21 are SEM views showing the cross-sectional and surface structures depending upon the thicknesses of CIGS thin-films prepared by the CIGS thin-film manufacturing method according to an embodiment of the present invention.

Referring to FIG. 20, it can be seen that the CIGS thin-films prepared by the CIGS thin-film manufacturing method according to an embodiment of the present invention are CIGS thin-films 130 having a different composition ratio, in which the CIGS thin-films 130 are prepared by using the CIS (CuInSe₂) single target 140a and the CGS (CuGaSe₂) single target 140b respectively having a composition ratio of stoichiometry, which shows the excellent bonding adhesion characteristics with respect to the substrate 110. Here, it can be seen that the thickness of the thin-film has a thickness gradient of about 2˜4 μm or so, the thin-film density goes high as it goes toward the sample “a” that is rich in CGS, and the grain size goes high as it goes toward the sample “f” that is rich in CIS.

Referring to FIG. 21, it can be seen that the CIGS thin-film prepared by the CIGS thin-film manufacturing method according to an embodiment of the present invention enables grain boundaries whose crystalline structures are clear to be observed at the surface thereof, and the grain size shows distribution of up to about 100 nm˜1 μm.

That is, it can be seen that as it goes to the CIS region sample “f,” the grain size is increased, and as it goes to the CGS region sample “a,” the thin-film packing density is increased. It can be seen that a large grain size and a high packing density of the CIGS thin-film prepared with only a single process by using the CIS-CGS single targets 140a and 140b have a very beneficial effect in view of an economy and efficiency of a process when compared to the manufacture of the absorption layer prepared by using a typical selenization process.

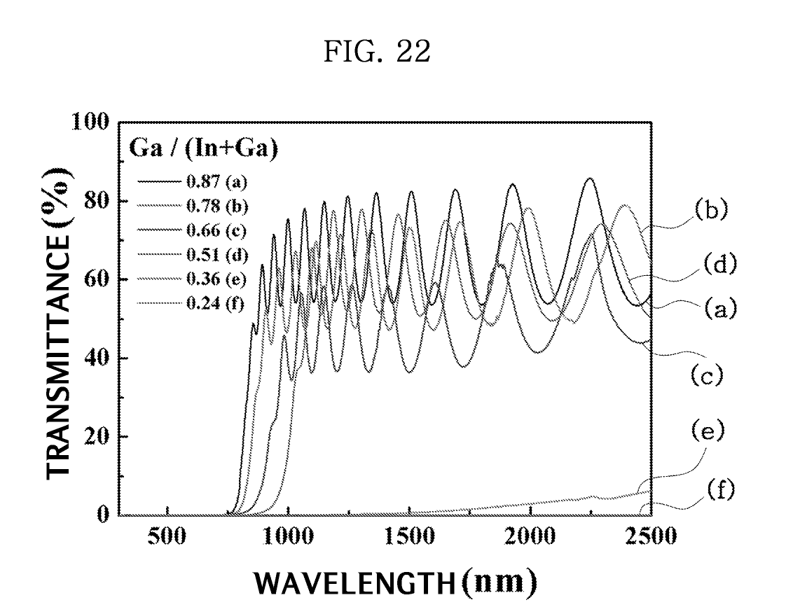

FIG. 22 shows the transmission characteristics of the CIGS thin-films fabricated by the CIGS thin-film manufacturing method according to an embodiment of the present invention, and in particular shows the transmission characteristics of the CIGS thin-films fabricated in accordance with the composition ratio of indium (In) and gallium (Ga).

Referring to FIG. 22, the transmittance characteristics of the thin-films were evaluated according to the composition ratio of (In, Ga) in the CIGS thin-film samples “a” to “f” in which the transmission characteristics of the CIGS thin-films were compared and analyzed according to the content of gallium (Ga). Here, the sample “a” shows the composition ratio of Ga/(In+Ga) is 0.87 at.%, and the sample “b” shows the composition ratio of Ga/(In+Ga) is 0.78 at.%, the sample “c” shows the composition ratio of Ga/(In+Ga) is 0.66 at.%, the sample “d” shows the composition ratio of Ga/(In+Ga) is 0.51 at.%, the sample “e” shows the composition ratio of Ga/(In+Ga) is 0.36 at.%, and the sample “s” shows the composition ratio of Ga/(In+Ga) is 0.24 at.%.

In the result of comparative analysis, as shown in the graph of FIG. 22, it can be seen that it is difficult to determine the initial absorption wavelength since the samples “e” and “f” are deposited very thickly with the thickness of the thin-film of about 4 μm or so. It can be seen that the transmission characteristics of the samples “a” to “d” except for the samples “e” and “f” showed the absorption wavelength having a constant ratio in accordance with the content ratio of gallium (Ga), and exhibited the distribution of the absorption peak in a wavelength of about 700-1200.

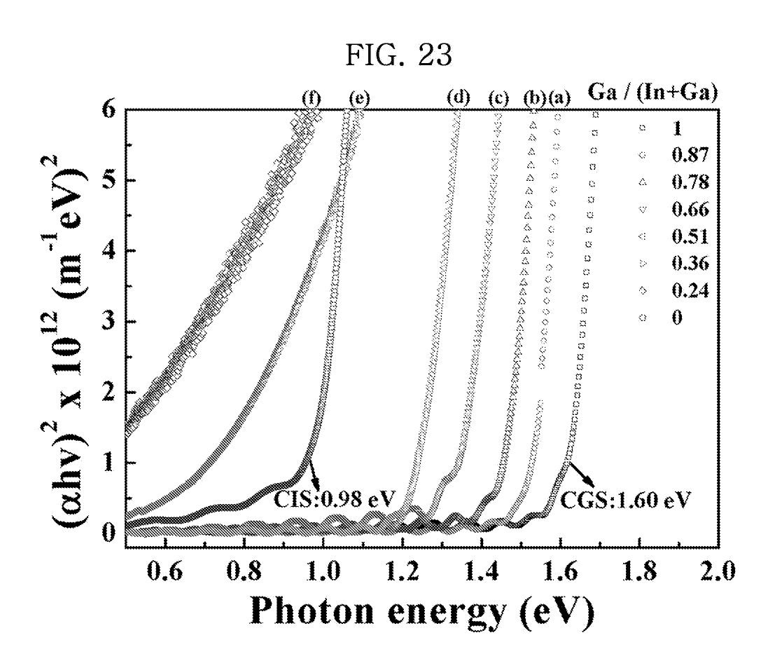

FIG. 23 is a graph showing a band gap characteristic according to the composition ratio of (In, Ga) of the CIGS thin-films prepared by the CIGS thin-film manufacturing method in accordance with an embodiment of the present invention, in which FIG. 23 illustrates the optical properties of the combinatorially deposited CIGS thin film by using the CIS-CGS single targets 140a and 140b, and shows the characteristic that the optical band gap is changed at a constant rate according to the content ratio of (In, Ga).

Referring to FIG. 23, the optical band gaps produced by the CIS and CGS single targets are 0.98 eV and 1.60 eV, respectively. In the case of the optical band gap of the CIGS thin-film that has been combinatorially deposited by using the two targets, A phenomenon can be confirmed that the optical band gap increases to 1.24˜1.52 eV at a constant rate as the content ratio of Ga/(In+Ga) increases to 0.51 to 0.87. This would mean that the composition ratio of (In, Ga) of the CIGS thin-films prepared with the sputtering method by using only the two different single targets could be easily controlled. In addition, it would be meant that the CIGS thin-films having a different composition can be manufactured to have a constant optical band gap according to the content ratio of (In, Ga).

As shown in the graph of FIG. 23, the thin-films of the samples “e” and “f” are rich in CIS (the respective contents of Ga=0.24 and 0.36), and the thicknesses of the deposited thin-films are at least 4 μm. Thus, since the thin-films of the samples “e” and “f” have the lower transmittance properties, the band gap properties cannot be ascertained.

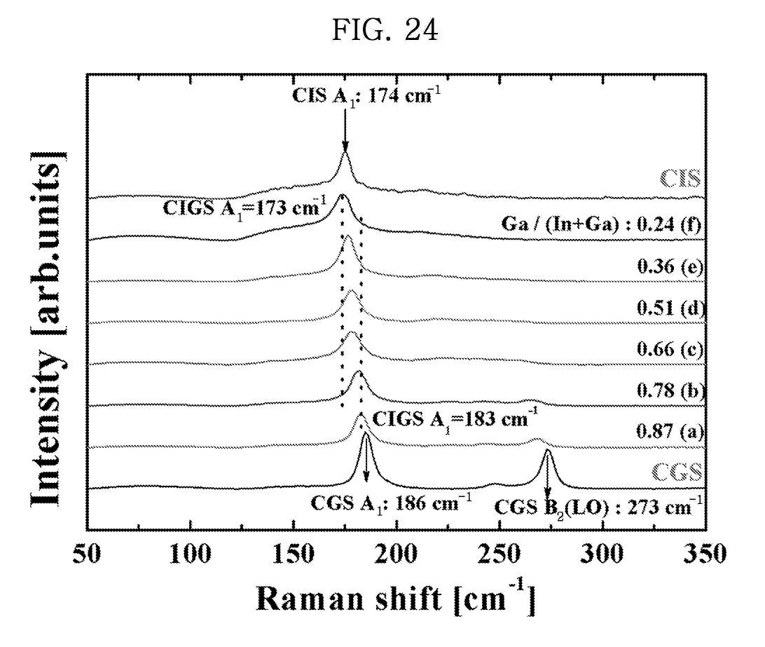

FIG. 24 is a graph showing Raman characteristics according to the composition ratio of (In, Ga) of the CIGS thin-films prepared by the CIGS thin-film manufacturing method according to an embodiment of the present invention.

Referring to FIG. 24, it was confirmed whether or not the monocrystallinity, polycrystallinity or secondary phases of the CIGS thin-films existed through Raman PL, and the phase shift that is changed at a constant rate depending on the content ratio of (In, Ga) was also observed. The Raman shift values of the samples produced with only the CIS and CGS single thin-films are 174 cm⁻¹ and 183 cm⁻¹, respectively, and the Raman shift values of the CIGS thin-films that were combinatorially deposited with the two targets were close to the positions of the CGS phase peaks as the content ratio of (In, Ga) went to the gallium (Ga) rich area, and were close to the positions of the CIS phase peaks as the content ratio of (In, Ga) went to the indium (In) rich area. In the results seen in the Raman PL characteristics, it was confirmed that the CIGS phase was constantly changing, depending on the composition ratio of (In, Ga) and it was demonstrated that the CIGS thin-film having a desired composition ratio could be prepared to have the excellent optical properties with only the sputtering method of the single process.

The A1 mode peak movement was observed in accordance with the content ratio of (In, Ga), which was confirmed as a phenomenon that occurs in accordance with the change in the composition of (In, Ga) in the CIGS thin-film. In addition, the very stable CIGS thin-films were manufactured in which the binary phase and the compositionally unstable third phase were not be verified.

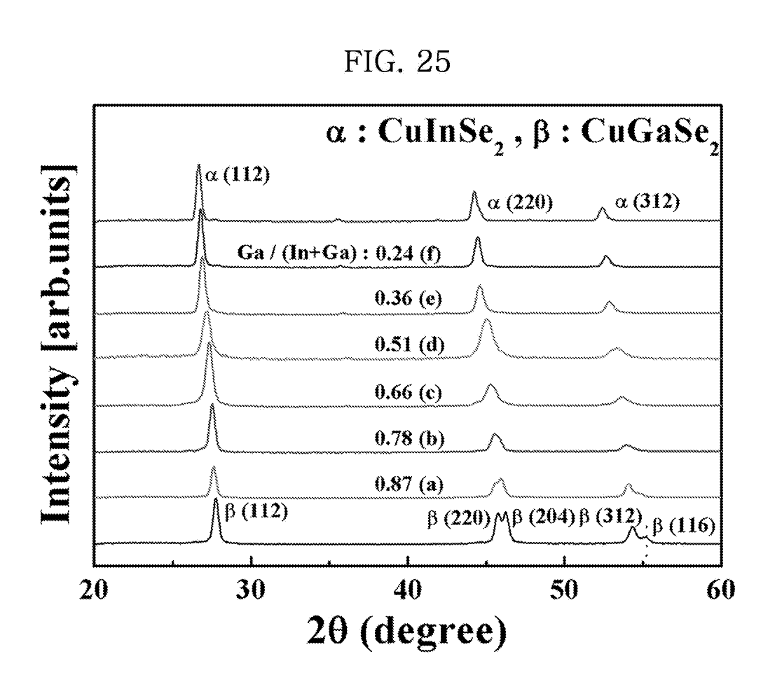

FIG. 25 is a graph showing XRD characteristics according to a composition ratio of (In, Ga) in a CIGS thin-film prepared by a CIGS thin-film manufacturing method according to an embodiment of the present invention, and in particular illustrates the results of comparing and analyzing the XRD characteristics of the CIGS thin-film produced according to the content ratio of (In, Ga), and the CIS and CGS single thin-films.

Referring to FIG. 25, it was observed that the diffraction peaks showing a chalcopyrite structure with respect to the CIS thin-film are α(112), α(220), and α(312), and the diffraction peaks representing the chalcopyrite structure of the CGS thin-film are β(112), β(220), β(204), β(312), and β(116). When the composition ratio is indicated by the content of gallium (Ga) the α sample has a value of zero, the β sample has a value of one, the samples “a” to “f” fabricated in accordance with the content ratio of Ga/(In+Ga) have the composition ratio of 0.24 to 0.87, respectively.

As can be seen from the graph of FIG. 25, it can be seen that when the content ratio of Ga/(In+Ga) in the CIGS thin-film sample increases, the sample is close to the diffraction peak having the CGS structure, and when the content ratio of Ga/(In+Ga) in the CIGS thin-film sample decreases, the sample is shifted to the diffraction peak having the CIS structure. The CIGS thin-film that is prepared by using the two single targets (i.e., the CIS and CGS single targets) can be prepared by controlling the content ratio of (In, Ga) in the CIGS thin-film. Only the diffraction peaks having only the chalcopyrite structure were observed in the CIGS thin-film having a specific composition ratio, and the diffraction peaks representing the second phase that lowers the efficiency of the absorbent layer such as the binary phase or the sphalerite structure were not observed.

As described above, the CIGS thin-films can be prepared through this experiment, in which the CIGS thin-films that are very stable crystallographically and can be controlled so as to be constantly shifted in accordance with the composition ratio of (In, Ga).

### MODE FOR INVENTION

As described above, the present invention has been described with respect to particularly preferred embodiments. However, the present invention is not limited to the above embodiments, and it is possible for one who has an ordinary skill in the art to make various modifications and variations, without departing off the spirit of the present invention. Thus, the protective scope of the present invention is not defined within the detailed description thereof but is defined by the claims to be described later and the technical spirit of the present invention.

### INDUSTRIAL APPLICABILITY

As described above, the CIS/CGS/CIGS thin-film manufacturing method and a solar cell manufactured by using the same according to the invention can be applied in industries for developing and applying CIS/CGS/CIGS thin-film solar cells.

1. A CIS/CGS/CIGS thin-film manufacturing method comprising the steps of:
(a) preparing a substrate;
(b) depositing an electrode layer on the substrate; and
(c) depositing a light absorber layer by sputtering a single target of each of CIS (CuInSe2) and CGS (CuGaSe2).

2. The CIS/CGS/CIGS thin-film manufacturing method of claim 1, wherein the depositing a light absorber layer of the step (c) comprises depositing a CIS light absorber layer by a RF sputtering or DC sputtering process by using a CIS single target including copper (Cu), indium (In), and selenium (Se).

3. The CIS/CGS/CIGS thin-film manufacturing method of claim 1, wherein the depositing a light absorber layer of the step (c) comprises depositing a CGS light absorber layer by a RF sputtering or DC sputtering process by using a CGS single target including copper (Cu), gallium (Ga) and selenium (Se).

4. The CIS/CGS/CIGS thin-film manufacturing method of claim 1, wherein the depositing a light absorber layer of the step (c) comprises depositing a CIGS light absorber layer by a simultaneous sputtering process by using a single target of each of CIS (CuInSe2) and CGS (CuGaSe2).

5. The CIS/CGS/CIGS thin-film manufacturing method of claim 2, wherein the sputtering process is performed under the process conditions of power of 100 W (1.23 W/cm²) to 300 W (3.70 W/cm²), process pressure of 0.1 to 1.0 Pa, time of 0.5 to 2 hr, and ambient temperature of the normal temperature to 550° C.

6. The CIS/CGS/CIGS thin-film manufacturing method of claim 1, wherein the single target of CIS (CuInSe2) has a composition ratio of copper (Cu) of 0.8 to 1.0 and accordingly a composition ratio of selenium (Se) is Se2+x in which x=0 to 0.2.

7. The CIS/CGS/CIGS thin-film manufacturing method of claim 1,
wherein the single target of CGS (CuGaSe2) has a composition ratio of copper (Cu) of 0.8 to 1.0 and accordingly a composition ratio of selenium (Se) is Se2+x in which x=0 to 0.2.

8. The CIS/CGS/CIGS thin-film manufacturing method of claim 6, wherein the single target is located at a distance spaced by 100 mm to 150 mm from the substrate.

9. The CIS/CGS/CIGS thin-film manufacturing method of claim 2, wherein the light absorber layer is characterized in that a thin-film thickness is regulated depending on the optical and structural properties.

10. The CIS/CGS/CIGS thin-film manufacturing method of claim 9, wherein a thin-film thickness of the CIS light absorber layer ranges from 0.1 μm to 2.0 μm.

11. The CIS/CGS/CIGS thin-film manufacturing method of claim 9, wherein a thin-film thickness of the CGS light absorber layer ranges from 0.3 μm to 2.2 μm.

12. The CIS/CGS/CIGS thin-film manufacturing method of claim 4, wherein a thin-film thickness of the CIGS light absorber layer has an absorption wavelength of a constant rate according to a content ratio of gallium (Ga) and represents an absorption peak distribution within a wavelength range of 700 to 1200.

13. The CIS/CGS/CIGS thin-film manufacturing method of claim 4, wherein a thin-film thickness of the CIGS light absorber layer has a constant optical band gap according to a content ratio of indium (In) and gallium (Ga).

14. The CIS/CGS/CIGS thin-film manufacturing method of claim 4, wherein a thin-film thickness of the CIGS light absorber layer has a phase that varies consistently according to a content ratio of indium (In) and gallium (Ga).

15. A solar cell that is prepared by the manufacturing method of claim 1.
